(19) United States
(12) Patent Application Publication
(10) Pub. No.: US 2010/0151685 A1
(43) Pub. Date: Jun. 17, 2010

(54) METHODS OF REMOVING MULTI-LAYERED STRUCTURE AND OF MANUFACTURING SEMICONDUCTOR DEVICE

(75) Inventor: Taizo YASUDA, Tokyo (JP)

Correspondence Address: YOUNG & THOMPSON, 209 Madison Street, Suite 500, Alexandria, VA, 22314, US

(73) Assignee: Elpida Memory, Inc., Tokyo (JP)

(21) Appl. No.: 12/635,037

(22) Filed: Dec. 10, 2009

(30) Foreign Application Priority Data
Dec. 12, 2008 (JP) 2008-317202

(51) Int. Cl. H01L 21/306

(52) U.S. Cl. 438/703; 438/706; 257/E21.219

(57) ABSTRACT

A method of removing a multi-layered structure includes the following processes. A semiconductor substrate is prepared. The semiconductor substrate has a multi-layered structure including a first film over the semiconductor substrate, a second film on the first film, and a mask pattern film on the second film. Then, the mask pattern film is removed. Then, the second film is removed by etching the second film with a first etching selectivity of the second film to the first film. The first etching selectivity is greater than a second etching selectivity of the second film to the first film with which the second film is patterned by etching using the mask pattern film. Then, the third film is removed.

### BACKGROUND OF THE INVENTION

1. Field of the Invention

The present invention relates to methods of removing a multi-layered structure and of manufacturing a semiconductor device. Particularly, the present invention relates to a method of removing a multi-layered structure, such as a multi-layered resist film, for rework in a semiconductor device manufacturing process.

Priority is claimed on Japanese Patent Application No. 2008-317202, filed Dec. 12, 2008, the content of which is incorporated herein by reference.

2. Description of the Related Art

With further miniaturization of semiconductor devices, there has been a demand for a mask which enables the resolution of photolithography to be enhanced and has an excellent dry etching resistance. As such a mask, a multi-layered resist film including a photoresist film is disclosed in, for example, Japanese Patent Laid-Open Publication Nos. 2008-197526, 2008-177532, and 2002-93778.

Japanese Patent Laid-Open Publication No. 2008-177532 discloses a multi-layered resist film including a silicon-containing photoresist film, as a technique of enhancing an etching resistance of the multi-layered resist film.

Japanese Patent Laid-Open Publication No. 2004-177668 discloses a multi-layered resist process for enhancing the pattern precision of a resist film by forming a photoresist layer for lithography for wirings so as to have a multi-layered structure including at least a lower layer made of an organic film, an intermediate layer, and a photoresist upper layer.

However, residue remains after the multi-layered film including a silicon containing film is removed, thereby occasionally affecting the following processes and the manufacturing yield.

In processes of manufacturing a semiconductor device having a multi-layered resist film, if defects in a pattern shape of the multi-layered resist film are found after exposure and development for forming the multi-layered resist film, the defective multi-layered resist film is removed to be reformed into a new multi-layered resist film (which is called “rework”). In this case, the defective multi-layered resist film is preferably completely removed. However, if the multi-layered resist film includes a silicon containing film, residue including a silicon compound remains, and therefore the multi-layered resist film cannot be completely removed in some cases.

Hereinafter, problems in the case of removing a multi-layered resist film including a silicon containing film using a conventional method upon reworking the multi-layered resist film are explained with reference to FIGS. 10 to 13.

FIGS. 10 to 13 are cross-sectional views indicative of a process flow illustrating a process of removing a multi-layered film including a silicon containing film for rework. FIGS. 10A to 13A are cross-sectional views illustrating the center of a semiconductor substrate (wafer). FIGS. 10B to 13B are cross-sectional views illustrating an outermost portion (bevel portion) of the semiconductor substrate.

FIG. 10A shows a state of a multi-layered resist film having been formed. Specifically, a film 2 to be processed, which is one of components forming a semiconductor device, is formed on a semiconductor substrate 1. Then, a three-layered film including a lower film 3, an intermediate film 4, and an upper film 5 is formed over the film 2. Then, exposure and development are carried out on the upper film 5 to form a pattern shape. Thus, the multi-layered resist film is formed.

To form the three-layered resist film shown in FIG. 10A, a solution to be a silicon-free organic film is applied by spin coating onto the film 2 to form the lower film 3. Then, a solution of SOG (Spin On Glass) is applied by spin coating onto the lower film 3 to form the intermediate film 4. Then, a silicon-free photoresist is applied by spin coating onto the intermediate film 4 to form the upper film 5. Then, the upper film 5 is subjected to exposure and development using a photomask so as to have a predetermined pattern shape for patterning the film 2 correspondingly to the photomask. Thus, the multi-layered resist film shown in FIG. 10A can be obtained.

As shown in FIG. 10A illustrating the center of the semiconductor substrate 1 when the multi-layered resist film is formed, the film 2, the lower film 3, the intermediate film 4, and the patterned upper film 5 are formed. As shown in FIG. 10B illustrating the bevel portion when the multi-layered resist film is formed, the film 2 does not completely cover an upper surface of the semiconductor substrate 1 (i.e., a side edge of the film 2 is inside a side edge of the semiconductor substrate 1). The lower film 3 covers the side edge of the semiconductor substrate 1.

Although the case where the film 2 does not completely cover the upper surface of the semiconductor substrate 1 has been explained in FIG. 10B, there is a case where the film 2 completely covers the upper surface, the side surface, and the lower surface of the semiconductor substrate 1.

As shown in FIG. 10B, the side edge of the upper film among the films 3, 4, and 5 is closer to the center of the semiconductor substrate 1. In other words, the side edge of the lower film 3 is close to the side edge of the semiconductor substrate 1. The side edge of the intermediate film 4 is inside the side edge of the lower film 3. The side edge of the upper film 5 is inside the side edge of the intermediate film 4. Accordingly, the upper film 5 is not shown at the bevel portion in FIG. 10B.

A thicker portion 4a that is three to four times thicker than the center of the intermediate film 4 is formed at the edge of the intermediate film 4 by centrifugal force generated by spin coating.

Hereinafter, a method of removing the multi-layered resist film shown in FIGS. 10A and 10B for rework by means of the following first to third steps is explained.

In the first step, the upper film 5 made of a resist film is removed using a solution generally used for removing a single-layered photoresist film, as shown in FIG. 11A. In this case, the intermediate film 4 is not removed, and therefore the thicker portion 4a at the bevel portion is not removed.

In the second step, the intermediate film 4 made of an SOG film and a part of the lower film 3 are removed by dry etching as shown in FIG. 12A. Generally, the dry etching is carried out using the same apparatus and the same gas condition as used in the case of patterning the intermediate film 4 using the upper film 5 as a mask. Generally, fluorocarbon gas, such as CF₄, is used for dry etching to pattern an SOG film using an upper resist film as a mask. Therefore, the intermediate film 4 is removed by dry etching using fluorocarbon gas in the second step.

Additionally, the dry etching condition in the second step is applicable to etching of the lower film 3 made of a silicon-free organic film. For this reason, the lower film 3 under the intermediate film 4 is also etched if the intermediate film 4 is removed in the second step, as shown in FIGS. 12A and 12B. Therefore, a dry-etching time is adjusted in the second step so that a part of the lower film 3 remains and the film 2 under the lower film 3 is not exposed at the end of the dry etching. Consequently, the thicker portion 4a of the intermediate film 4 remains as residue 4b at the bevel portion at the end of the second step, as shown in FIG. 12B.

In the third step, the lower film 3 is removed by oxygen gas ashing, as shown in FIG. 13A. In this case, the lower film 3 made of a silicon-free organic film is removed, but the intermediate film 4 made of an SOG film is not removed. For this reason, the residue 4b remains on the semiconductor substrate 1 after the lower film 3 is removed, as shown in FIG. 13B. Although FIG. 13B illustrates the case where the residue 4b remains at the bevel portion, the residue 4b may remain on the center of the semiconductor substrate 1 in another case.

The reside 4b remaining after the multi-layered resist film is removed causes a decrease in the manufacturing yield. For this reason, the manufacturing yield is likely to decrease if the multi-layered resist film is removed for rework using the conventional removing method.

To solve the above problems, for example, Japanese Patent Lain-Open Publication No. 2008-177532 discloses a technique of removing silicon compound reside in a rework process for removing a silicon-containing organic film by lithography. However, the disclosed technique requires a dedicated apparatus and chemicals for a cleaning process, resulting in manufacturing costs. Further, the technique is not applicable to the case where an SOG film is used as a silicon containing film, and therefore another removing method is required.

### SUMMARY

In one embodiment, a method of removing a multi-layered structure includes the following processes. A semiconductor substrate is prepared. The semiconductor substrate has a multi-layered structure including a first film over the semiconductor substrate, a second film on the first film, and a mask pattern film on the second film. Then, the mask pattern film is removed. Then, the second film is removed by etching the second film with a first etching selectivity of the second film to the first film. The first etching selectivity is greater than a second etching selectivity of the second film to the first film with which the second film is patterned by etching using the mask pattern film. Then, the third film is removed.

In another embodiment, a method of removing a multi-layered structure includes the following processes. A multi-layered structure is formed. The multi-layered structure includes first to third films. The second film is between the first and third films. The first film is free of silicon. The second film contains silicon. The third film is a resist film. Then, the third film is patterned. Then, it is determined whether or not the multi-layered structure is defective after patterning the third film. If the multi-layered structure is determined not to be defective, the second film is patterned by dry etching using the third film patterned as a mask. If the multi-layered structure is determined to be defective, the multi-layered structure is removed. The process of removing the multi-layered structure includes removing the second film by dry etching under a condition that a difference between a first etching rate of the first film and a second etching rate of the second film is greater than that when the second film is patterned by dry etching.

In still another embodiment, a method of manufacturing a semiconductor device includes the following processes. A multi-layered structure is formed. The multi-layered structure includes first to third films. The second film is between the first and third films. The first film is free of silicon. The second film contains silicon. The third film is a resist film. Then, the third film is patterned. Then, it is determined whether or not the multi-layered structure is defective after patterning the third film. If the multi-layered structure is determined not to be defective, the second film is patterned by dry etching under a first gas atmosphere using the third film patterned as a mask. Then, the first film is patterned by dry etching using the second film patterned as a mask. If the multi-layered structure is determined to be defective, the multi-layered structure is removed. The process of removing the multi-layered structure includes removing the second film by dry etching under a second gas atmosphere different from the first gas atmosphere.

Accordingly, in the process of removing the second film containing silicon, the second film is completely removed by selective etching while the first film remains, thereby preventing silicon compound residue from remaining. Therefore, a multi-layered structure including a silicon containing film can be easily and completely removed for rework. Further, a decrease in the manufacturing yield caused by the rework can be prevented.

### BRIEF DESCRIPTION OF THE DRAWINGS

The above features and advantages of the present invention will be more apparent from the following description of certain preferred embodiments taken in conjunction with the accompanying drawings, in which:

FIGS. 1 to 9 are cross-sectional views indicative of a process flow illustrating a method of forming element isolation regions, which is included in a semiconductor device manufacturing method of the present invention; and

FIGS. 10 to 13 are cross-sectional views indicative of a process flow illustrating a method of removing a multi-layered resist film including a silicon containing film for rework, which is included in the semiconductor device manufacturing method of the present invention.

### DETAILED DESCRIPTION OF THE PREFERRED EMBODIMENTS

The present invention will now be described herein with reference to illustrative embodiments. The accompanying drawings explain a semiconductor device and a method of manufacturing the semiconductor device in the embodiments. The size, the thickness, and the like of each illustrated portion might be different from those of each portion of an actual semiconductor device.

Those skilled in the art will recognize that many alternative embodiments can be accomplished using the teachings of the present invention and that the present invention is not limited to the embodiments illustrated herein for explanatory purposes.

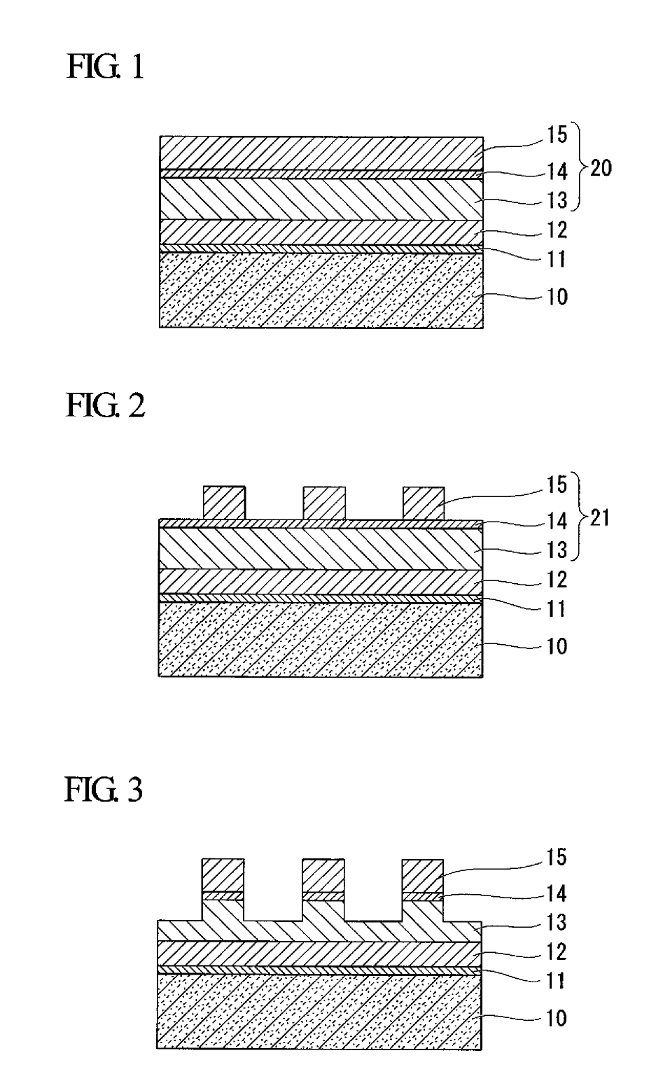

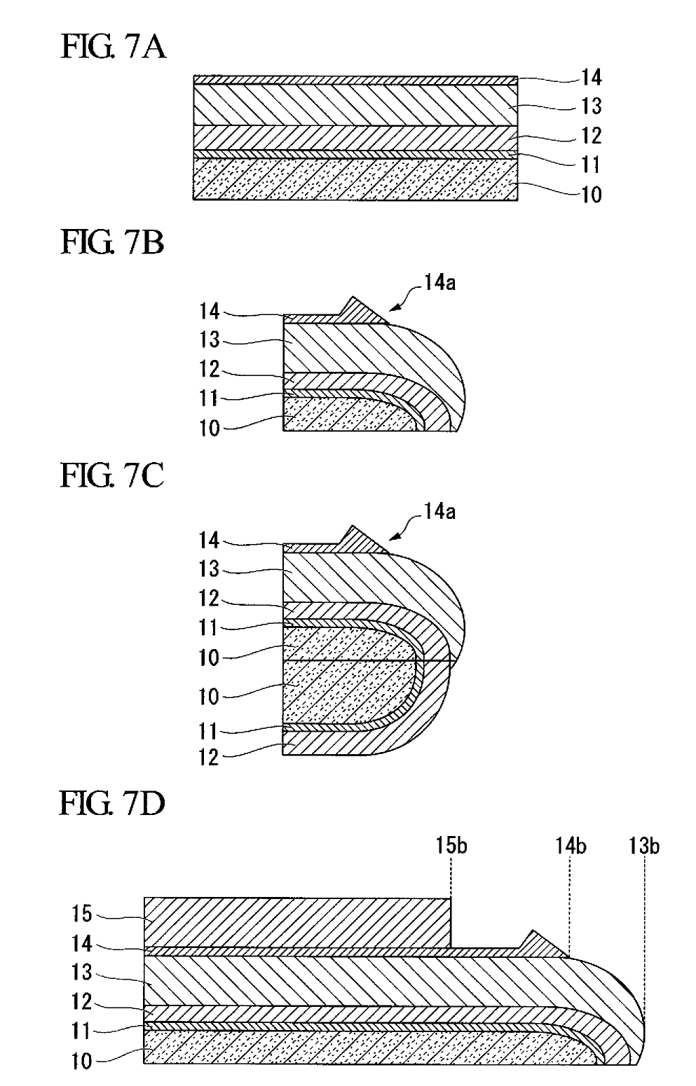

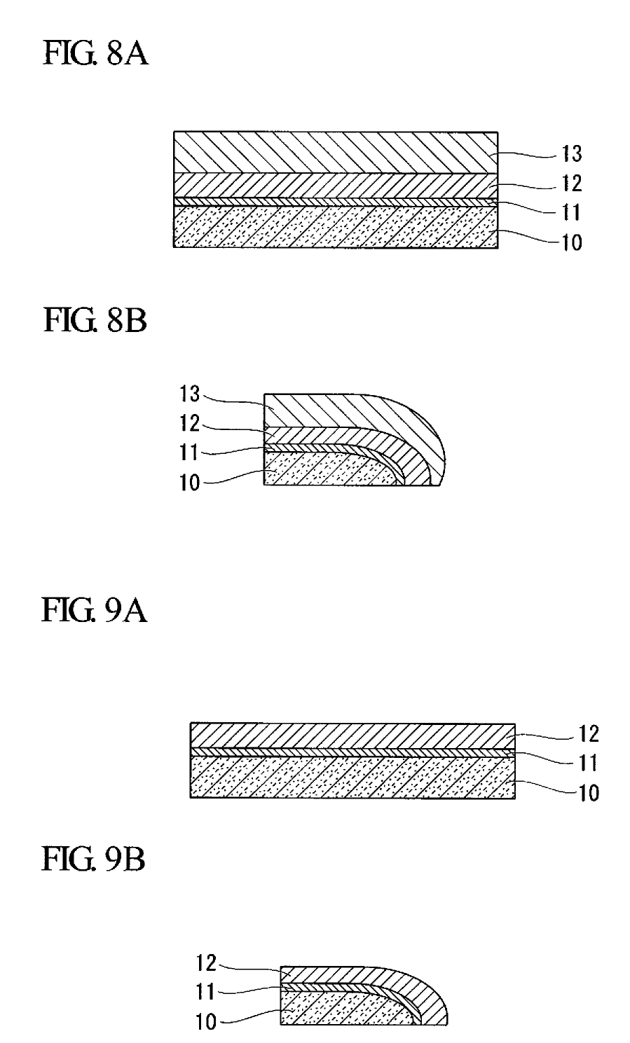

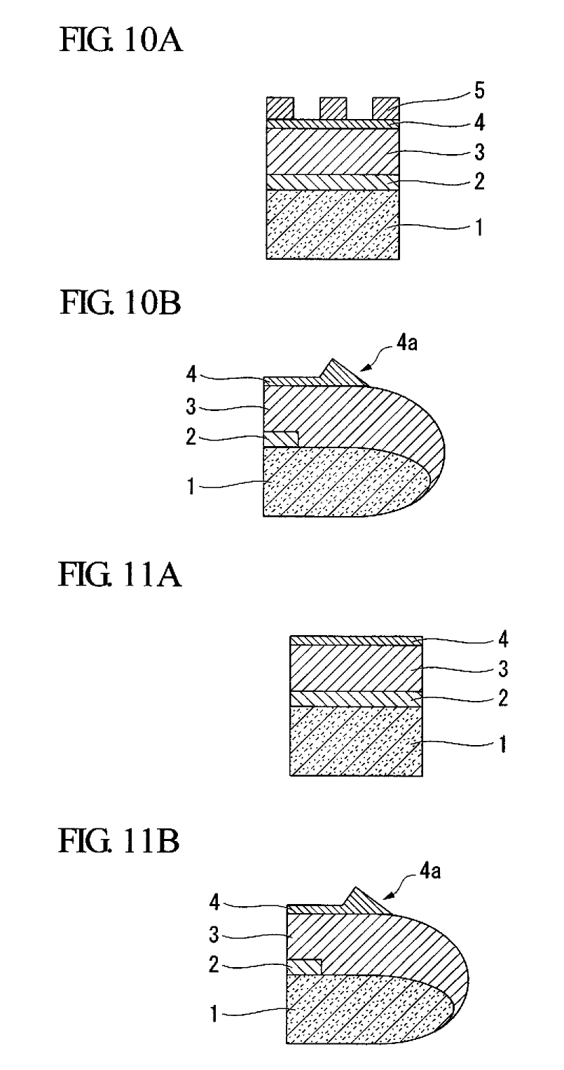

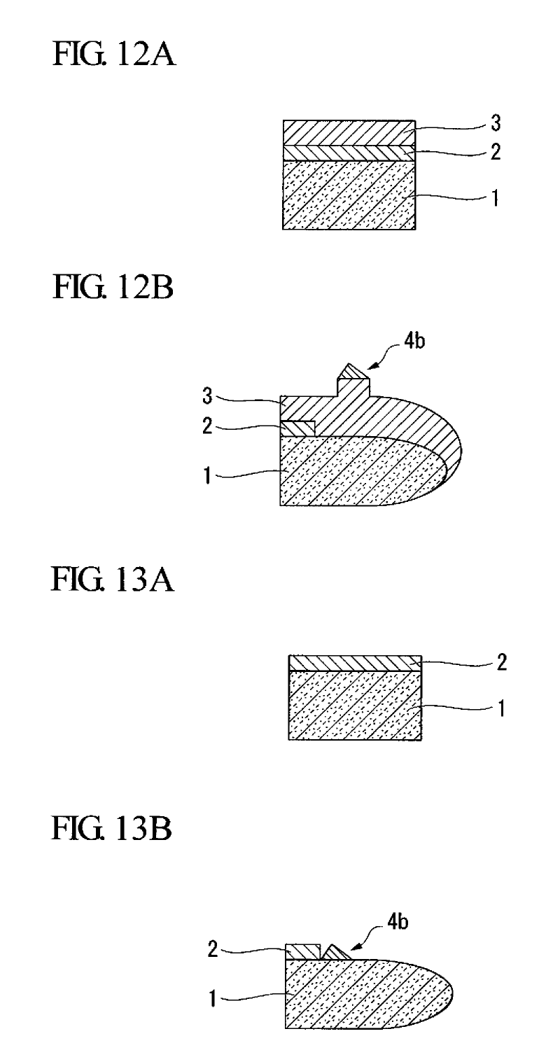

FIGS. 1 to 9 are cross-sectional views indicative of a process flow illustrating a method of forming element isolation regions using STI (Shallow Trench Isolation), which is included in a semiconductor device manufacturing method of the present invention. Only a main side of a semiconductor substrate is shown in FIGS. 1 to 9. FIGS. 7A to 9A are cross-sectional views illustrating the center of the semiconductor substrate (wafer). FIGS. 7B to 9B are cross-sectional views illustrating the outermost portion (bevel portion) of the semiconductor substrate.

FIG. 1 illustrate a state of a multi-layered film 20 formed on a silicon nitride film 12 after a silicon oxide film (SiO₂) 11 and the silicon nitride film (Si₃N₄) 12 are formed on a semiconductor substrate 10 in this order. The multi-layered film 20 is a three-layered film including a lower film (first film) 13, an intermediate film (second film) 14, and an upper film (third film) 15 which are deposited on the silicon nitride film 12 in this order.

The semiconductor substrate 10 is made of silicon. The silicon oxide film 11 is formed on the semiconductor substrate by thermal oxidization. The silicon nitride film 12 is formed on the silicon oxide film 11 by CVD (Chemical Vapor Deposition).

The multi-layered film 20 having a three-layered structure is formed by the following processes. Firstly, a carbon containing solution is applied over the silicon nitride film 12 by spin coating to form the lower film 13 made of a silicon-free organic film. The lower film 13 has a thickness of, for example, 200 nm to 300 nm. The lower film 13 functions as a mask for the silicon oxide film 11 and the silicon nitride film 12 to be etched. Further, the lower film 13 functions as BARC (Bottom Anti-Reflection Coating) to prevent light from reflecting from the underlying film upon exposure for patterning the upper film 15.

Then, an SOG solution is applied over the lower film 13 by spin coating to form the intermediate film 14 made of a silicon containing film. The intermediate film 14 has a thickness of, for example, 30 nm to 500 nm.

Then, a photoresist not containing silicon, which is used for exposure with an ArF light source, is applied over the intermediate film 14 by spin coating to form the upper film 15 made of a resist film. Thus, the multi-layered film 20 is formed. The upper film 15 has a thickness of, for example, 100 nm to 120 nm.

The film structure of the multi-layered film 20 is not limited thereto, and a film material, the thickness, the number of deposited layers, or the like can be modified.

Then, the upper film 15 is subjected to exposure and development for patterning using a photomask having a desired element formation pattern. As a result, the upper film 15 has a predetermined pattern shape corresponding to the photomask. Thus, the multi-layered resist film 21 (multi-layered mask) having the three-layered structure including the lower film 13, the intermediate film 14, and the patterned upper film 15 is formed.

Then, it is determined whether or not the multi-layered resist film 21 is defective. Criteria for the determination vary according to, for example, the required precision of the pattern shape. If the multi-layered resist film 21 is not defective, the intermediate film 14 is patterned by dry etching using the upper film 15 as a mask. If the multi-layered resist film 21 is defective, the multi-layered resist film 21 is removed.

Here, the case where the multi-layered resist film 21 is defective, and therefore the multi-layered resist film 21 shown in FIG. 2 is completely removed for rework is explained.

Firstly, the shape of each layer above the semiconductor substrate 10 when a process of removing the multi-layered resist film 21 is initiated is explained in detail for simplification of the explanations.

At the bevel portion shown in FIG. 7B, the silicon oxide film 11 covers an upper surface of the semiconductor substrate 10. The silicon nitride film 12 covers an upper surface of the silicon oxide film 11. The lower film 13 covers an upper surface of the silicon nitride film 12. Although only the top surface side of the semiconductor substrate 10 is shown in FIG. 7B, the silicon oxide film 11 may cover top, side, and bottom surfaces of the semiconductor substrate 10, as shown in FIG. 7C. Additionally, the silicon nitride film 12 may cover top, side, and bottom surfaces of the silicon oxide film 11. The lower film 13 is formed by spin coating, and is therefore formed only on the top surface side of the semiconductor substrate 10.

As shown in FIG. 7B, a thicker portion 14a that is three to four times thicker than the center of the wafer is formed at the edge of the intermediate film 14 by centrifugal force generated by spin coating.

As shown in FIG. 7D, the side edge of the upper film among the films 13, 14, and 15 is disposed closer to the center of the semiconductor substrate 10. In other words, a side edge 14b of the intermediate film 14 is inside a side edge 13b of the lower film 13. A side edge 15b of the upper film 15 is inside the side edge 14b of the intermediate film 14.

According to this structure, the silicon oxide film 11 and the silicon nitride film 12 can be prevented from remaining at the bevel portion when the multi-layered film 21 is removed. Further, the silicon oxide film 11 and the silicon nitride film 12 can be prevented from peeling away.

To remove the multi-layered resist film 21, a solution generally used for removing a photoresist film, such as PGMEA (Propylene Glycol Monomethyl Ether Acetate), is used to remove the upper film 15 made of a resist film. In this case, the intermediate film 14 is not removed, and the thicker portion 14a at the bevel portion remains.

Then, the intermediate film 14 is removed by dry etching under a condition such that the difference between the etching rate of the lower film 13 and the etching rate of the intermediate film 14 is greater than that when the intermediate film 14 is patterned by dry etching if the multi-layered resist film 21 is not defective.

In the present embodiment, the intermediate film 14 made of a silicon containing film, and a part of the lower film 13 are removed by dry etching using SF₆ gas. Preferably, the dry etching is carried out using an ICP-RIE (Inductive Coupled Plasma-Reactive Ion Etching) apparatus with mixed gas including SF₆ gas (at flow volume in the range of 90 sccm to 110 sccm), O₂ gas (at flow volume in the range of 10 sccm to 20 sccm), and HBr gas (at flow volume in the range of 90 sccm to 110 seem), at pressure in the range of 4 mTorr to 7 mTorr, at source power in the range of 1000 W to 1100 W, and at bias power in the range of 50 W to 60 W.

Not only the intermediate film 14, but also a part of the lower film 13 is removed by the dry etching. However, the difference between the etching rate of the lower film 13 and the etching rate of the intermediate film 14 (selectivity) is greater in the case of the dry etching using SF₆ gas. Therefore, the intermediate film 14 is selectively removed, and the removed amount of the lower film 13 is less than the removed amount of the intermediate film 14. For this reason, even if the etching is carried out until the thicker portion 14a at the bevel portion is completely removed, a sufficient amount of the lower film 13 not disposed under the thicker portion 14a can remain after the etching.

Preferably, the etching rate of the intermediate film 14 for removing the intermediate film 14 is 1.6 times greater than that of the lower film 13. In this case, the difference in the etching rate of the lower film 13 and the etching rate of the intermediate film 14 (selectivity) is sufficiently large, and therefore the intermediate film 14 can be selectively dry-etched.

Then, the lower film 13 is removed by, for example, oxygen plasma ashing so that the surface of the silicon nitride film 12 is exposed. Thus, the multi-layered resist film 21 is completely removed.

Then, the multi-layered film 20 having the three-layered structure including the silicon nitride film 12 (first film), the intermediate film 14 (second film), and the upper film 15 (third film) is formed on the silicon nitride film 12 in a similar manner to that explained above, as shown in FIG. 1. Then, the upper film 15 is subjected to exposure and development using a photomask having a predetermined element isolation pattern. As a result, the upper film 15 has a predetermined pattern corresponding to the photomask. Thus, the multi-layered resist film 21 having the three-layered structure including the lower film 13, the intermediate film 14, and the patterned upper film 15 is formed again. The multi-layered resist film 21 is reworked in this manner.

Then, it is determined again whether or not the multi-layered resist film 21 is defective. If the multi-layered resist film 21 is not defective, the intermediate film 14 is patterned by dry etching using the upper film 15 as a mask. If the multi-layered resist film 21 is defective, the rework process is carried out again, and then it is determined again whether or not the multi-layered resist film 21 is defective.

Here, the case where the multi-layered resist film 21 is not defective, and therefore the intermediate film 14 is patterned by dry etching using the upper film 15 as a mask is explained as an example.

In the present embodiment, the intermediate film 14 is patterned by anisotropic dry etching with fluorocarbon gas using the patterned upper film 15 as a mask, as shown in FIG. 3. Preferably, the dry etching is carried out using an RIE apparatus with mixed gas including CH₄ gas (at flow volume in the range of 240 sccm to 260 sccm) and CHF₃ gas (at flow volume in the range of 30 sccm to 50 sccm), and at pressure in the range of 35 mTorr to 45 mTorr, at RF power in the range of 400 W to 450 W. In this case, the intermediate film 14 can be anisotropically etched with fluorocarbon gas without the upper film 15 being changed in shape. As a result, the pattern of the upper film 15 can be precisely transferred to the intermediate film 14.

As shown in FIG. 3, the surface of the lower film 13 is slightly etched by dry etching the intermediate film 14. Even if the lower film 13 is completely removed by dry etching the intermediate film 14, the silicon nitride film 12, a part of which will be etched later, is exposed, thereby causing no problem. For this reason, the etching rate of the intermediate film 14 may be less than 1.6 times the etching rate of the lower film 13.

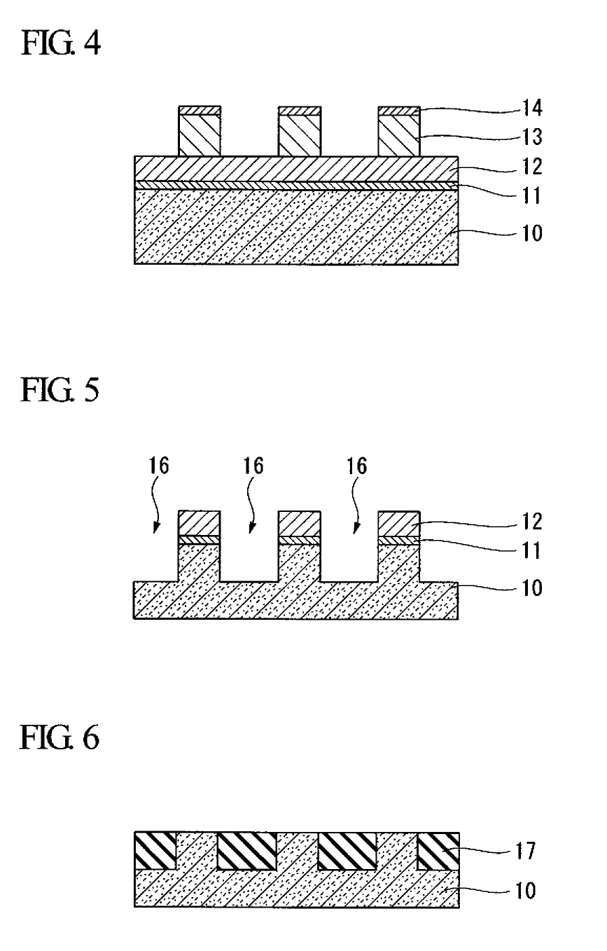

Then, the lower film 13 is patterned by anisotropic dry etching using the upper film 15 and the intermediate film 14 as masks, as shown in FIG. 4. In this case, the upper film 15 remaining after the patterning of the intermediate film 14 is also etched while the intermediate film 14 exposed after the upper film 15 is removed serves as a mask. Therefore, the pattern shape firstly formed in the upper film 15, which corresponds to the predetermined element isolation pattern, is transferred to the lower film 13, as shown in FIGS. 2 to 4.

Then, the silicon oxide film 11 and the silicon nitride film 12 are patterned by anisotropic dry etching using the lower film 13 and the intermediate film 14 as masks, as shown in FIG. 5. In this case, the intermediate film 14 remaining after the lower film 13 is patterned is also etched while the lower film 13 exposed after the intermediate film 14 is removed serves as a mask. Therefore, the pattern shape firstly formed in the upper film 15 is transferred to the silicon oxide film 11 and the silicon nitride film 12. At the same time, the thicker portion 14a at the bevel portion is also completely removed.

Then, the lower film 13 remaining after etching the silicon oxide film 11 and the silicon nitride film 12 is removed by, for example, oxygen plasma ashing. Thus, the multi-layered resist film 21 is completely removed.

Then, the silicon forming the semiconductor substrate 10 exposed after the silicon oxide film 11 and the silicon nitride film 12 are removed is anisotropically dry etched using the silicon nitride film 12 as a mask to form a groove pattern 16 in the semiconductor substrate 10.

Then, a silicon oxide film 17 is deposited to fill the groove pattern 16. Then, the surfaces of the semiconductor substrate 10 and the silicon oxide film 17 are planarized while the silicon nitride film 12 and the silicon oxide film 11 are removed at the same time. Thus, element isolation regions are completed as shown in FIG. 6.

According to the present embodiment, the silicon-containing intermediate film 14 on the silicon-free lower film 13 is removed by dry etching using SF₆ gas to rework the multi-layered resist film 21. Accordingly, the intermediate film 14 can be selectively removed while a sufficient amount of the lower film 13 remains, thereby preventing residue containing silicon compound from remaining without causing damage to the silicon nitride film 12. Therefore, a decrease in the manufacturing yield of the semiconductor device caused by rework of the multi-layered resist film 21 can be prevented.

Although the process of forming element isolation regions has been explained in the present embodiment as an example, the present invention is not limited thereto. The present invention is also applicable to the case of removing a multi-layered film including a first film not containing silicon and a second film that is disposed over the first film and contains silicon.

### Example

As a silicon-free organic film used as a lower film forming a multi-layered resist film, a BARC film made of a phenolic resin containing carbon at approximately 85% by weight was formed by spin coating. Additionally, an SOG film was formed by spin coating, as a silicon containing film used as an intermediate film forming the multi-layered resist film. Then, the BARC film and the SOG film are dry etched under the conditions 1 and 2 to measure the etching rate of the organic film not containing silicon (lower film) and the etching rate of the silicon containing film (intermediate film) and to calculate the selectivity of the intermediate film to the lower film (intermediate film/lower film). The conditions 1 is that the amount of CH₄ is 240 sccm, the amount of CHF₃ is 30 sccm, pressure is 40 mTorr, high-frequency power is 400 W. The conditions 2 is that the amount of SF₆ is 90 sccm, the amount of O₂ is 10 sccm, the amount of HBr is 90 sccm, pressure is 4 mTorr, source power is 1000 W, and bias power is 50 W. Chart 1 illustrates the calculation result.

As understood from chart 1, the intermediate film can be etched at the etching rate 1.68 times faster than that of the lower film if the dry etching with SF₆ gas is carried out under Condition 2.

CHART 1

| | CONDITION 1 | CONDITION 2 |
|---|---|---|
| INTERMEDIATE FILM | 193.5 nm/min | 221.6 nm/min |
| LOWER FILM | 152.8 nm/min | 131.9 nm/min |
| SELECTIVITY | 1.26 | 1.68 |

For this reason, it is assumed that a multi-layered resist film including the lower film made of the BARC film and the intermediate film made of the SOG film is formed on a film on a wafer. Even if the intermediate film is removed by dry etching under Condition 2 such that a thicker portion of the intermediate film at a bevel portion of the wafer is completely removed, a sufficient amount of the lower film can remain compared with the case of dry etching under Condition 1. Therefore, the multi-layered resist film can be removed for rework without damaging the film to be processed.

It is apparent that the present invention is not limited to the above embodiments, but may be modified and changed without departing from the scope and spirit of the invention.

As used herein, the following directional terms “forward, rearward, above, downward, vertical, horizontal, below, and transverse” as well as any other similar directional terms refer to those directions of a device equipped with the present invention. Accordingly, these terms, as utilized to describe the present invention should be interpreted relative to a device equipped with the present invention.

The terms of degree such as “substantially,” “about,” and “approximately” as used herein mean a reasonable amount of deviation of the modified term such that the end result is not significantly changed. For example, these terms can be construed as including a deviation of at least ±5 percent of the modified term if this deviation would not negate the meaning of the word it modifies.

What is claimed is:

1. A method of removing a multi-layered structure comprising:
preparing a semiconductor substrate having a multi-layered structure comprising a first film over the semiconductor substrate, a second film on the first film, and a mask pattern film on the second film;
removing the mask pattern film;
removing the second film by etching the second film with a first etching selectivity of the second film to the first film, the first etching selectivity being greater than a second etching selectivity of the second film to the first film with which the second film is patterned by etching using the mask pattern film; and
removing the third film.

2. The method according to claim 1, wherein the first film is free of silicon, the second film contains silicon, and the mask pattern film is a photo resist film.

3. The method according to claim 2, wherein
the first etching selectivity is equal to or greater than 1.6, and
the second etching selectivity is smaller than 1.6.

4. The method according to claim 2, wherein removing the second film comprises dry etching the second film using SF₆ gas.

5. The method according to claim 2, wherein the second film is patterned by dry etching using fluorocarbon gas.

6. The method according to claim 5, wherein the fluorocarbon gas contains at least one of CF₄ and CHF₃.

7. The method according to claim 2, wherein the second film is formed by spin-coating an SOG solution over the first film.

8. The method according to claim 1, wherein
the first film contains carbon, and
removing the first film comprises oxygen plasma ashing.

9. The method according to claim 1, wherein
the multi-layered structure further comprises a fourth film for patterning by using the mask pattern film,
the fourth film is disposed between the first film and the semiconductor substrate, and
a surface of the fourth film is covered by the first film after removing the second film.

10. The method according to claim 1, wherein, in preparing the semiconductor substrate, a side edge of the second film is outside a side edge of the mask pattern film, and a side edge of the first film is outside the side edge of the second film.

11. A method of removing a multi-layered structure comprising:
forming a multi-layered structure comprising first to third films, the second film being between the first and third films, the first film being free of silicon, the second film containing silicon, and the third film being a resist film;
patterning the third film;
determining whether or not the multi-layered structure is defective after patterning the third film;
patterning the second film by dry etching using the third film patterned as a mask if the multi-layered structure is determined not to be defective; and
removing the multi-layered structure if the multi-layered structure is determined to be defective, removing the multi-layered structure comprising removing the second film by dry etching under a condition that a difference between a first etching rate of the first film and a second etching rate of the second film is greater than that when patterning the second film by dry etching.

12. The method according to claim 11, wherein the second etching rate is equal to or more than 1.6 times the first etching rate when removing the second film by dry etching.

13. The method according to claim 11, wherein removing the multi-layered structure comprises removing the second film by dry etching using SF₆ gas.

14. The method according to claim 11, wherein patterning the second film comprises patterning the second film by dry etching using fluorocarbon gas.

15. The method according to claim 11, wherein forming the multi-layered structure comprises forming the second film by spin-coating an SOG solution over the first film.

16. The method according to claim 11, wherein removing the multi-layered film comprising removing the first film by oxygen plasma ashing after removing the second film.

17. A method of manufacturing a semiconductor device comprising:
forming a multi-layered structure comprising first to third films, the second film being between the first and third films, the first film being free of silicon, the second film containing silicon, and the third film being a resist film;
patterning the third film;
determining whether or not the multi-layered structure is defective after patterning the third film;
patterning the second film by dry etching under a first gas atmosphere using the third film patterned as a mask if the multi-layered structure is determined not to be defective;
patterning the first film by dry etching using the second film patterned as a mask; and
removing the multi-layered structure if the multi-layered structure is determined to be defective, removing the multi-layered structure comprising removing the second film by dry etching under a second gas atmosphere different from the first gas atmosphere.

18. The method according to claim 17, wherein
patterning the second film comprises patterning the second film by dry etching under a first condition that a first etching rate of the second film is less than 1.6 times a second etching rate of the first film, and
removing the second film comprises removing the second film by dry etching under a second condition that a third etching rate of the second film is equal to or more than 1.6 times a fourth etching rate of the first film.

19. The method according to claim 17, wherein
removing the multi-layered structure comprises removing the second film by dry etching using SF₆ gas, and
patterning the second film comprises patterning the second film by dry etching using fluorocarbon gas.

20. The method according to claim 19, wherein the fluorocarbon gas contains at least one of CF₄ and CHF₃.
